(19) United States
(12) Patent Application Publication
(10) Pub. No.: US 2013/0128480 A1
(43) Pub. Date: May 23, 2013

(54) CIRCUIT ARRANGEMENT FOR ELECTRONIC AND/OR ELECTRICAL COMPONENTS

(71) Applicant: Robert Bosch GmbH, Stuttgart (DE)

(72) Inventor: Alexander Bareiss, Immenstadt (DE)

(73) Assignee: Robert Bosch GmbH, Stuttgart (DE)

(21) Appl. No.: 13/680,810

(22) Filed: Nov. 19, 2012

(30) Foreign Application Priority Data
Nov. 21, 2011 (DE) 10 2011 086 707.4

(51) Int. Cl. H05K 7/06

(52) U.S. Cl. CPC H05K 7/06
USPC 361/760

(57) ABSTRACT

A circuit arrangement includes at least one electronic and/or electrical component and a carrier. The at least one electronic and/or electrical component is conductively connected to the carrier by at least one solder layer while forming an air space between the electronic and/or electrical component and the carrier. At least one three-dimensional mounting structure is integrated in the carrier and the at least one electronic and/or electrical component is arranged axially between at least two contact regions of the mounting structure.

This application claims priority under 35 U.S.C. §119 to patent application no. DE 10 2011 086 707.4, filed on Nov. 21, 2011 in Germany, the disclosure of which is incorporated herein by reference in its entirety.

### BACKGROUND

The disclosure relates to a circuit arrangement for electronic and/or electrical components.

A circuit arrangement usually comprises a carrier and at least one electronic and/or electrical component, to which electrical contact is made. Here, electronic and/or electrical components are predominantly fitted on flat carriers, in particular on flat printed circuit boards. At the same time, the circuit arrangement is optimized with regard to its processing and/or the fitted electronic and/or electrical components and/or the printed circuit board materials and/or the manufacturing process, thus enabling the circuit arrangement to be manufactured in a cost-effective manner. Thermal and/or mechanical stresses on the electronic and/or electrical components and/or the electrical connecting points, which occur for example between the printed circuit board and the electronic and/or electrical component, and the causes of the thermal and mechanical stresses are known. Amongst other things, a different thermal expansion of the materials is possible due to different material characteristics of the electronic and/or electrical components and of the printed circuit board, which can lead to the occurrence of mechanical stresses, such as shear stresses for example, and possibly to damage, such as disintegration of the solder for example. Depending on the given boundary conditions, the necessary countermeasures and/or test methods for checking the stability, for example, of electrical connecting points are very elaborate.

So-called MIDs (Molded Interconnecting Devices), which enable the production of three-dimensional or spatial conductor carriers, are also known. These MID circuit carriers differ from the above-mentioned flat circuit carriers, for example, in that they can easily be used as spatial conductor carriers. In the meantime, as a result of progress in the manufacturing process, there are also elements which are made entirely of plastic without combining with pre-manufactured metallic insert parts and which, in a two-component injection process, either have a metallizable plastic component and an insulating component or, as a result of a single-component injection process and laser treatment, can be metalized in defined regions and therefore used as a circuit carrier. A direct mounting of the electronic and/or electrical components on such MID parts often fails due to the problem of the different materials and their characteristics. For example, in the event of different thermal expansion, this can lead to a failure of the conducting connection between the electronic and/or electrical component and the MID part, which, in operation, can lead to a malfunction which cannot be accurately predicted. If this connection is considered more closely, then it can be seen that shear stresses in particular, which can occur, for example, due to the geometry of a solder connection, are rather unfavorable for the durability of the design. With printed circuit boards however, no other solution can expediently be implemented due to the two-dimensionality.

A component in chip design having an electronic function body which is fixed to a circuit board is described by way of example in the application DE 38 13 435 A1. Here, the electronic function body is fitted in a pre-manufactured, cup-shaped housing which is made from insulating material. The housing protects the electronic function body against external influences.

An electrical capacitor which is designed in the form of a chip component is described by way of example in the application DE 34 12 492 A1. The capacitor described comprises a capacitor body, on the opposite faces of which are applied metal platings, to which are fixed strips of bendable metal which protrude from a casing and form solder surfaces along the surface of the casing.

### SUMMARY

In contrast with this, the circuit arrangement according to the disclosure for electronic and/or electrical components has the advantage that at least one three-dimensional mounting structure, in which the at least one component is arranged axially between at least two contact regions of the mounting structure, is integrated in a carrier. In this way, geometric degrees of freedom of a three-dimensional carrier resulting from the spatial arrangement are used in an advantageous manner in order to mitigate and/or reduce effects which can occur due to unequal thermal expansion and/or mechanical stresses. An example of such an effect is a shear stress which acts between the carrier and the electronic and/or electrical component and therefore on the solder connection. Reducing thermal and/or mechanical stresses enables the durability of the electrical connections and therefore of the circuit arrangement to be increased in an advantageous manner.

Embodiments of the present disclosure provide a circuit arrangement having at least one electronic and/or electrical component and a carrier. Here, the at least one electronic and/or electrical component is conductively connected to the carrier by means of at least one solder layer while forming an air space between the electrical component and the carrier. According to the disclosure, a three-dimensional mounting structure, in which the at least one electronic and/or electrical component is arranged axially between at least two contact regions of the mounting structure, is integrated into the carrier.

The three-dimensional mounting structure can be implemented easily and cost-effectively, for example by means of the available additional characteristics of MID components, in order to reduce or eliminate the mechanical stresses in the electrical connecting points. Depending on the geometrical design, as a result of the connecting point alone, a shear stress can be converted into a more compatible tensile stress, or even be reduced by a “flexible” design of the connecting point so that it does not damage the electrical connection. The electronic and/or electrical components can then be arranged directly on the three-dimensional MID conductor carriers without having to take a detour via additional flat printed circuit boards, which naturally simplifies the structure and altogether considerably improves the design options with regard to installation space.

The measures and improvements listed in the dependent claims enable advantageous improvements of the circuit arrangement for electronic and/or electrical components to be made.

It is particularly advantageous that the at least one three-dimensional mounting structure has at least two contact carriers with, in each case, at least one contact region, wherein the at least one component is arranged in a free space between the at least two contact carriers. In an advantageous manner, shear stresses in particular can be reduced by the connection between the at least two contact carriers and the geometry of the resulting solder connection. Here, the solder paste can be applied to the appropriate points in the carrier or in the mounting structure, and the component ideally inserted afterwards, wherein the order of events is variable. The solder connection, which is produced by reflow soldering for example, is formed automatically and draws the solder mass and the component into the optimum position. Other known connection techniques and corresponding connection methods, such as laser soldering for example, can equally be used in an advantageous manner.

In a further advantageous embodiment of the circuit arrangement according to the invention, the at least one three-dimensional mounting structure has a depression, wherein the associated walls of the depression form the at least two contact carriers. To implement this, pockets and/or notches and/or recesses for example can be formed in the carrier. In an advantageous manner, the electronic component can be connected axially instead of with solder fillets as before. Furthermore, in an advantageous manner, the mounting structure can be enclosed around the component by means of the walls and/or be left open on at least one side. In this way, the mounting structure can be matched to the specified form and/or geometry of the carrier. Furthermore, this solution saves space and simplifies the design of the mounting structure. In addition, in an advantageous manner, the design options with regard to the installation space can be altogether improved. Furthermore, in an advantageous manner, this enables components to be satisfactorily integrated into the carrier and reduces the shear stresses.

In a further advantageous embodiment of the circuit arrangement according to the invention, the at least two contact carriers protrude from the carrier. In this way, the at least two contact carriers of the three-dimensional mounting structure are implemented as so-called bending beams. Here, in an advantageous manner, the material of the contact carriers is chosen so that, when stresses or displacements occur, the bending beam is deformed so that, in an advantageous manner, the loads are dissipated and as a result only a reduced part-load acts on the electrical connecting point. In an advantageous manner, various details of the geometrical designs can be combined with known elements in any way to simplify reliable assembly and positioning accuracy. The forming process used here, for example an injection molding process, also offers various geometric alternatives.

In a further advantageous embodiment of the circuit arrangement according to the disclosure, the carrier can consist of a plastic pre-molded part made from galvanizable plastic and a second, non-galvanizable plastic, wherein a metal film with specified dimensions is applied in a galvanic process to the regions of the carrier made from galvanizable plastic. Here, the carrier can be manufactured, for example, by means of a MID-2K technique (MID: Molded Interconnected Device), i.e. the injection-molded carrier consists of two components which comprise a galvanizable plastic which is partially coated with a second, non-galvanizable plastic. The partially protruding surfaces of the pre-molded part are coated with a metallic surface by means of a galvanic process in order to produce exposed circuit paths, contact surfaces injection-molded etc. The use of such an, MID carrier is particularly suitable in the present application, as the miniaturization of circuit carrier arrangements can be advanced thanks to the improved design freedom and the integration of electrical and mechanical functions. Furthermore, the additional three-dimensional formation of stress-relieving elements can be conveniently implemented in this way.

Optionally, this MID carrier can also be structured directly by means of a laser. The MID circuit carrier then consists of an injection-molded part with which the locations of the circuit paths are structured with the help of a laser and then coated with a metallic surface by means of a galvanic process, thus producing the exposed circuit paths, contact surfaces, etc.

In a further advantageous embodiment of the circuit arrangement according to the disclosure, the at least two contact carriers can include regions of galvanizable plastic and regions of non-galvanizable plastic. In this way, in an advantageous manner, the contact carrier can be matched and implemented in a variable manner. Furthermore, in an advantageous manner, additional characteristics of the contact carriers can be realized with this manufacturing technique.

In a further advantageous embodiment of the circuit arrangement according to the disclosure, the metal film can be applied to at least two surfaces of the respective contact carrier which are substantially at right angles to one another. The metallization can be formed at required positions on the surface of the MID carrier and “around the corner” into the depression in the MID carrier. These embodiments can be implemented without any problems by the usual manufacturing methods, such as injection molding, laser structuring or galvanizing for example. In an advantageous manner, this enables the component to be mounted satisfactorily.

In a further advantageous embodiment of the circuit arrangement according to the invention, the metal film can be formed as a contact region and/or as a circuit path. In an advantageous manner, a simple connection which is matched in form and dimensions can be implemented.

In a further advantageous embodiment of the circuit arrangement according to the disclosure, the at least two contact carriers can have a specified elastic behavior so that, in an advantageous manner, the tensile stress can be transmitted directly without shear stresses occurring. Depending on the geometrical design, as a result of the connecting point alone, the shear stress can be converted into a more compatible tensile stress or even be reduced by “flexible” design to such an extent that it does not damage the electrical connection.

In a further advantageous embodiment of the circuit arrangement according to the disclosure, at least one supporting element can be arranged between the at least two contact carriers in the at least one mounting structure. A support, on which the component can rest, can therefore be formed, for example, in the depression or between the two protruding contact carriers.

### BRIEF DESCRIPTION OF THE DRAWINGS

Exemplary embodiments of the disclosure are shown in the drawing and are explained in more detail in the following description. In the drawing, the same references designate components or elements which carry out the same or similar functions.

FIG. 1 shows a schematic sectional view of a first exemplary embodiment of a circuit arrangement according to the disclosure.

FIG. 2 shows an enlarged section of the circuit arrangement shown in FIG. 1.

FIG. 3 shows a sectional view of a second exemplary embodiment of a circuit arrangement according to the disclosure.

FIG. 4 shows an enlarged section of the circuit arrangement shown in FIG. 3.

### DETAILED DESCRIPTION

In the known circuit arrangements, components are fitted on flat printed circuit boards and, if necessary, combined with MID parts to form a three-dimensional connection. In the case of flat printed circuit boards, shear stresses, which can cause damage to the electrical connection and/or the component, can occur.

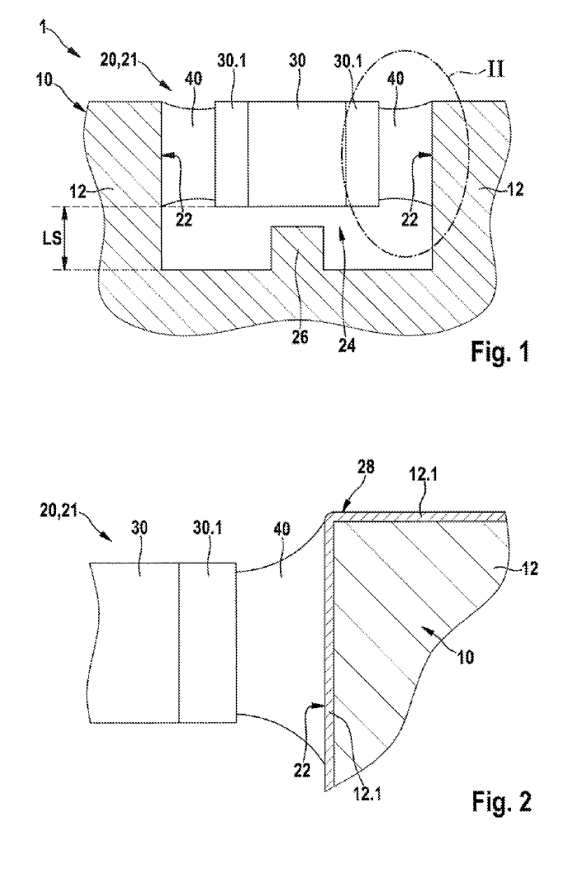

As can be seen from FIGS. 1 to 4, the shown exemplary embodiments of a circuit arrangement 1, 1′ according to the disclosure comprise an electronic and/or electrical component 30, 30′ and a carrier 10, 10′. The electronic and/or electrical component 30, 30′ is conductively connected to the carrier 10, 10′ by means of a solder layer 40, 40′ while forming an air space LS, LS′ between the electrical component 30, 30′ and the carrier 10, 10′. In the exemplary embodiments shown, the electronic and/or electrical component 30, 30′ has a contact region 30.1, 30.1′, which is constructed from a metal or some other electrically conducting material, on each face. Furthermore, in the exemplary embodiments shown, in each case the entire face of the component 30, 30′ is designed as a contact region 30.1, 30.1′. In addition, the component 30, 30′ is connected to the carrier 10, 10′ only at the contact regions 30.1, 30.1′ after the corresponding solder layers 40, 40′ have been formed. In an alternative embodiment, which is not shown, it is not necessary for the entire face of the component to be used as the contact region.

According to the disclosure, at least one three-dimensional mounting structure 20, 20′, in which the at least one component 30, 30′ is arranged axially between at least two contact regions 22, 22′ of the mounting structure 20, 20′, is integrated in the carrier 10, 10′.

As can be further seen from FIGS. 1 to 4, the at least one three-dimensional mounting structure 20, 20′ has at least two contact carriers 12, 12′, each having at least one contact region 22, 22′, wherein the at least one component 30, 30′ is arranged in a free space 24, 24′ between the at least two contact carriers 12, 12′.

As can be further seen from FIGS. 1 to 4, at least one supporting element 26, 26′, on which the electronic and/or electrical component 30, 30′ is placed before the soldering process, is arranged in the mounting structure 20, 20′ between the at least two contact carriers 12, 12′. The corresponding solder layers 40, 40′ form automatically during the soldering process and draw the solder mass and the electronic and/or electrical component 30, 30′ into the optimum position.

In the exemplary embodiments shown, the carrier 10, 10′ of the circuit arrangement 1, 1′ is produced as a plastic pre-molded part made of galvanizable first plastic and a second, non-galvanizable plastic, wherein, in a galvanic process, a metal film 12.1, 12.1′ with specified dimensions is applied to the regions of the carrier 10, 10′made of galvanizable plastic. Here, the contact surfaces can take almost any desired form. The contact carriers 12, 12′ of the carrier 10, 10′ likewise comprise regions made of galvanizable plastic which are coated with a metal, such as, for example, copper, nickel, silver, gold, etc. A variable configuration of the contact carriers 12, 12′ is therefore possible, such that the contact regions 12.1, 12.1′ of the contact carriers 12, 12′ are rendered electrically conducting and an electrical insulation on the contact carriers 12, 12′ is also possible. Furthermore, a contact carrier 12, 12′ can also have a plurality of contact surfaces 12.1, 12.1′, enabling a plurality of components 30, 30′ to be fixed and electrically connected. Furthermore, the two contact carriers 12, 12′ have a specified elastic behavior enabling shear stresses to be converted into tensile stress.

As can be further seen from FIGS. 1 and 2, in a first exemplary embodiment, the three-dimensional mounting structure 20 includes a depression 21, wherein the associated walls 12 of the depression 21 form the at least two contact carriers 12. The depression 21 can, for example, be a notch which is open in at least one spatial direction, and/or an enclosed hollow space with any geometrical shape. The corresponding contact surfaces 12.1 lie opposite to one another in the depression 21, wherein the carrier 10 itself can have any geometrical shape. In the first exemplary embodiment, the carrier is designed as a plate with a rectangular base surface in which the depression is made.

As can be further seen from FIG. 2, the metal film 12.1 is applied “around the corner” to at least two surfaces of the respective contact carrier 12 which are substantially at right angles to one another. Here, the metal film 12.1 on the wall of the depression 21 forms a contact region 22 and, outside the depression 21, a circuit path 28. The electronic and/or electrical component 30 is connected to an electronic and/or electrical circuit, which is not shown in detail, by means of the respective contact region 22 and the corresponding circuit path 28.

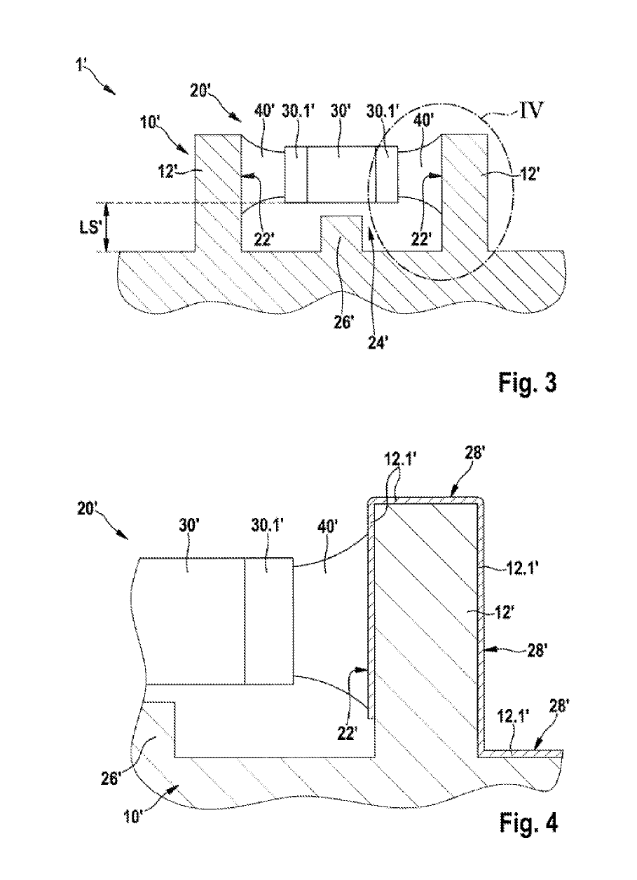

As can be further seen from FIGS. 3 and 4, the two contact carriers 12′ protrude from the surface of the carrier 10′. The protruding contact carriers 12′ can be fixed to the base surface of the carrier or designed in one piece with the carrier 10′.

As can be further seen from FIG. 4, the metal layer 12.1′ is applied to at least two surfaces of the respective contact carrier 12′ which are substantially at right angles to one another. Here, the metal film 12.1′ forms a contact region 22′ and/or a circuit path 28′, wherein the electronic and/or electrical component 30′ is electrically connected by means of the circuit path 28′. As can be further seen from FIG. 4, the protruding contact carriers 12′ have a filigree design so that, when mechanical stresses or displacements occur, the contact carrier 12′ deforms or bends in order to at least partially relieve the loads which occur. As a result, only a reduced part load acts on the electrical connecting point 40.

What is claimed is:

1. A circuit arrangement, comprising:
at least one electronic and/or electrical component;
a carrier; and
at least one three-dimensional mounting structure integrated in the carrier,
wherein the at least one electronic and/or electrical component is conductively connected to the carrier by at least one solder layer so as to form an air space between the electronic and/or electrical component and the carrier, and
wherein the at least one electronic and/or electrical component is arranged axially between at least two contact regions of the mounting structure.

2. The circuit arrangement according to claim 1, wherein the at least one three-dimensional mounting structure has at least two contact carriers with each contact carrier having at least one contact region, and wherein the at least one electronic and/or electrical component is arranged in a free space between the at least two contact carriers.

3. The circuit arrangement according to claim 2, wherein the at least one three-dimensional mounting structure has a depression, and wherein associated walls of the depression form the at least two contact carriers.

4. The circuit arrangement according to claim 2, wherein the at least two contact carriers protrude from the carrier to form the three-dimensional mounting structure.

5. The circuit arrangement according to claim 2, wherein the carrier includes a plastic pre-molded part made from galvanizable plastic and a second, non-galvanizable plastic, and wherein a metal film with a specified form and specified dimensions is applied in a galvanic process to the regions of the carrier made from galvanizable plastic.

6. The circuit arrangement according to claim 5, wherein the at least two contact carriers include regions of galvanizable plastic and regions of non-galvanizable plastic.

7. The circuit arrangement according to claim 5, wherein the metal film is applied to at least two surfaces of the respective contact carrier which are substantially at right angles to one another.

8. The circuit arrangement according to claim 5, wherein the metal film forms a contact region and/or a circuit path.

9. The circuit arrangement according to claim 2, wherein the at least two contact carriers have a specified elastic behavior.

10. The circuit arrangement according to claim 2, wherein at least one supporting element is arranged between the at least two contact carriers in the at least one mounting structure.
